(19) United States
(12) Patent Application Publication
(10) Pub. No.: US 2020/0337173 A1
(43) Pub. Date: Oct. 22, 2020

(54) BACKPLATE AND PROTECTIVE COVER FOR ELECTRONIC PRODUCT

(71) Applicant: BOE TECHNOLOGY GROUP CO., LTD., Beijing (CN)

(72) Inventors: Zifeng WANG, Beijing (CN); Junmin SUN, Beijing (CN); Lei CAO, Beijing (CN); Yan REN, Beijing (CN)

(21) Appl. No.: 16/956,706

(22) PCT Filed: Oct. 23, 2019
(86) PCT No.: PCT/CN2019/112748

§ 371 Date: Jun. 22, 2020

(30) Foreign Application Priority Data
Nov. 22, 2018 (CN) 201821931731.8

(51) Int. Cl. H05K 7/14; H05K 5/03; H05K 5/02

(52) U.S. Cl. CPC H05K 7/1438; H05K 5/0221; H05K 5/03; H05K 7/1401

(57) ABSTRACT

A backplate includes a backplate body, a movable portion and an ejection structure. The backplate body includes an elastic material and has an edge portion and a central portion. The movable portion is arranged at a peripheral edge of the backplate body. The ejection structure is arranged on the backplate body and has a first operating state. The ejection structure is configured to eject the edge portion of the backplate body and the movable portion in a direction away from the central portion of the backplate body when it is in the first operating state, so that the edge portion of the backplate body extends in the direction away from the central portion thereof.

### CROSS REFERENCE TO RELATED APPLICATIONS

The present application is a 35 U.S.C. 371 national stage application of PCT International Application No. PCT/CN2019/112748, filed on Oct. 23, 2019, which claims the benefit of a Chinese Patent Application No. 201821931731.8, filed on Nov. 22, 2018, the contents of which are incorporated herein by reference in their entireties.

### TECHNICAL FIELD

The disclosure relates to the technical field of decorative frames, in particular to a backplate and a protective cover for an is electronic product.

### BACKGROUND

With the increasing popularity of electronic products (e.g. digital art products such as electronic picture screens or electronic photo frames), the requirements on appearance of electronic products are also getting higher and higher. Take electronic picture screen products as an example. In electronic picture screen products, wooden frames are usually used. However, due to the limitations of their own material properties and machining process, wooden frames cannot guarantee high precision tolerances with other assembly parts. For example, when assembling, it is difficult to avoid the gap between the frame and the picture screen (i.e. the display screen), which is a big defect for the appearance of digital art products.

### SUMMARY

In view of this, in one aspect, some exemplary embodiments of the present disclosure provide a backplate for an electronic product, which includes a backplate body, a movable portion, and an ejection structure. The backplate body includes an elastic material and has an edge portion and a central portion. The movable portion is arranged at the peripheral edge of the backplate body. The ejection structure is arranged on the backplate body and has a first operating state. The ejection structure is configured to eject the edge portion and the movable portion of the backplate body in a direction away from the central portion of the backplate body when it is in the first operating state, so that the edge portion of the backplate body extends in a direction away from the central portion thereof.

Optionally, the movable portion is embedded in the edge portion of the backplate body, or alternatively the movable portion is disposed around the edge of the backplate body.

Optionally, the ejection structure comprises a locking portion and an ejecting portion, wherein the locking portion is arranged at a first end of the ejection structure and is used for connecting the backplate body and a front object of the electronic product; and the ejecting portion is arranged at a second end of the ejection structure and moves synchronously with the locking portion and is used for ejecting the movable portion or the edge portion of the backplate body. The front object is, for example, a display module of the electronic product.

Optionally, the ejection structure takes a shape of an odd-shaped lock screw as a whole.

Optionally, an outer periphery of the locking portion is provided with locking threads, the ejecting portion is coaxially arranged with the locking portion and rotates synchronously with the locking portion, and a maximum diameter of the ejecting portion is larger than a diameter of the locking portion.

Optionally, the locking portion of the ejection structure is cylindrical with a uniform diameter, a first portion of the ejecting portion adjacent to the locking portion is cylindrical with a diameter slightly smaller than the diameter of the locking portion, a second portion of the ejecting portion at a certain distance from the locking portion in an axial direction is in a shape of a projection, and the outer periphery of the projection is a smooth cylindrical surface.

Optionally, the projection is at least partially disposed at a periphery of the second portion of the ejecting portion, and the outer diameter of the projection gradually increases along the circumferential direction of the second portion.

Optionally, a maximum outer diameter of the projection is referred to as a first length L1, and a projecting distance of the projection relative to the first portion of the ejecting portion in a radial direction of the ejecting portion is referred to as a second length L2, then a maximum value of L2 is 10%-40% of L1, and a size of the first length L1 is equal to a maximum gap distance between the backplate body and the frame of the electronic product.

Optionally, the ejection structure is a conical screw, the diameter of the ejecting portion and the diameter of the locking portion gradually decrease in a direction from a head portion to a tail portion of the conical screw, and the maximum diameter of the ejecting portion is equal to a maximum gap distance between the backplate body and the frame of the electronic product.

Optionally, the backplate further comprises an ejector rod, wherein the ejector rod is arranged between the movable portion and the ejection structure, and a first end of the ejector rod is in abutting engagement with the movable portion, and a second end of the ejector rod is in contact with the ejection structure.

Optionally, the movable portion is a strip-shaped movable bar, and the adjacent movable bars are not in contact with each other.

Optionally, the backplate further comprises a reinforcing portion, the reinforcing portion is arranged in an area of the backplate body other than the movable portion, and the reinforcing portion is a rigid grid structure.

Optionally, the movable portion and the ejection structure comprise rigid materials.

On the other hand, some exemplary embodiments of the present disclosure also provide a protective cover for an electronic product, which includes:

the backplate for an electronic product mentioned above; and

a frame arranged at the peripheral edge portion of the backplate and forming an accommodating space with the backplate for accommodating a front object of the electronic product.

### BRIEF DESCRIPTION OF THE DRAWINGS

FIG. 1A is a schematic structural view of a digital art product;

FIG. 1B is a sectional view taken along the direction A-A in FIG. 1A;

FIG. 2 is an improved sectional view of the digital art product of FIG. 1B;

FIG. 3 is a schematic structural view of an electronic product provided by some exemplary embodiments of the present disclosure;

FIG. 4 is a sectional view taken along the X-X direction in FIG. 3, wherein the electronic product is in a first operating state;

FIG. 5 is a sectional view taken along the X-X direction in FIG. 3, wherein the electronic product is in a second operating state;

FIG. 6A is a schematic structural view of an ejection structure provided by some exemplary embodiments of the present disclosure;

FIG. 6B is a side view of the ejection structure provided in FIG. 6A;

FIG. 7 is another schematic structural view of an ejection structure provided by some exemplary embodiments of the present disclosure;

FIG. 8 is a schematic structural view of another electronic product provided by some exemplary embodiments of the disclosure;

FIG. 9 is a schematic structural view of a backplate provided by some exemplary embodiments of the disclosure; and

FIG. 10 is a schematic structural view of another backplate provided by some exemplary embodiments of the disclosure.

### DETAILED DESCRIPTION OF THE DISCLOSURE

With reference to the drawings and some exemplary embodiments, the specific embodiments, structures, features and effects of the backplate and protective cover proposed in accordance with the present disclosure will be described in detail below. In the following description, various “one embodiment” or “some embodiments” refer to not necessarily the same embodiment. In addition, certain features, structures, or characteristics in one or more embodiments may be freely combined to achieve benefits.

With the increasing popularity of electronic products (e.g. digital art products such as electronic picture screens or electronic photo frames), the requirements on appearance of electronic products are also increasing. Take electronic picture screen products as an example. In electronic picture screen products, wooden frames are usually used. However, due to the limitations of their own material properties and machining process, wooden frames cannot guarantee high precision tolerances with other assembly parts. For example, during assembly, it is difficult to avoid the gap between the frame and the picture screen (i.e. the display screen).

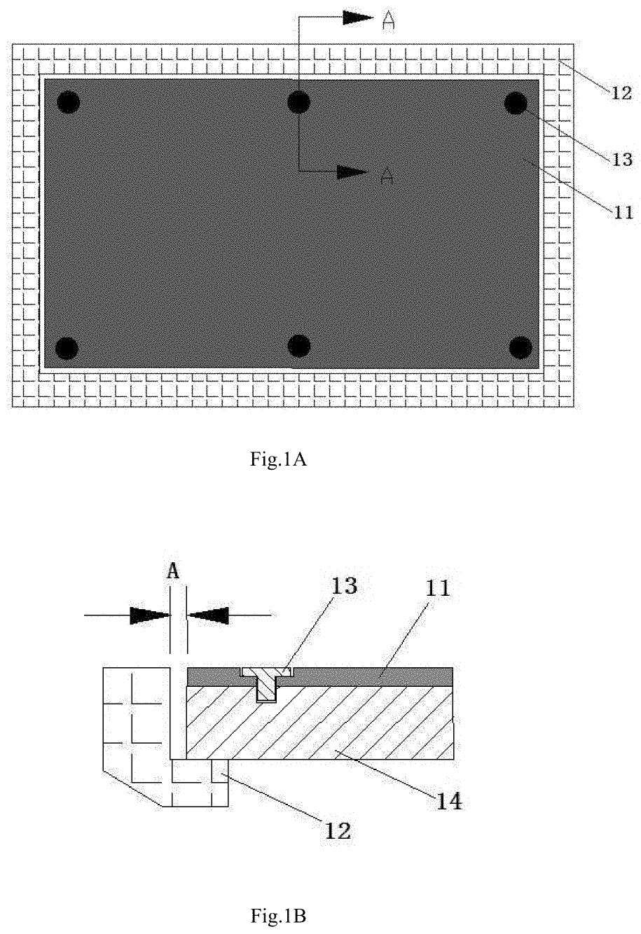

FIG. 1A and FIG. 1B (FIG. 1B is a sectional view along the direction A-A of FIG. 1A) schematically show a structure of a digital art product. The digital art product comprises a frame 12, a backplate 11, screws 13 and a display module 14. The frame 12 and the backplate 11 are made of wood material, for example. Due to the large tolerance of the wood material itself and the influence of the environment, the tolerances of the frame 12 and the backplate 11 made of wood material are generally one order of magnitude larger than those of the frame 12 and the backplate 11 made of metal or plastic. Therefore, after normal assembly, there will be a relatively large gap A between the backplate 11 and the frame 12.

In the related digital electronic product shown in FIGS. 1A and 1B, since there is a large gap A between the backplate 11 and the is frame 12 after assembly, the overall appearance of the digital art product is not aesthetically pleasing.

Hereinafter, the inventors of the present application further improved the related digital electronic product shown in FIGS. 1A and 1B.

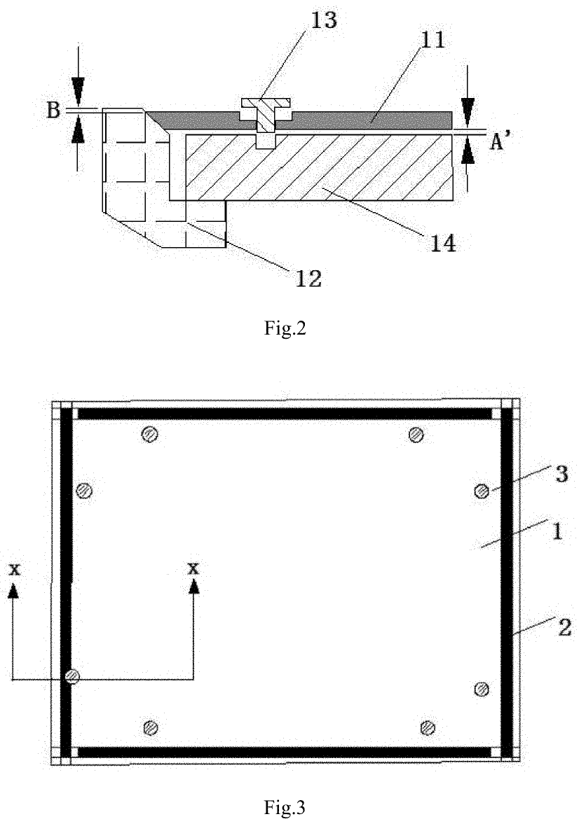

Referring to FIG. 2, the inventors of the present application made the cooperating vertical surfaces of the frame 12 and the backplate 11 to be sloped surfaces (or bevels). After such improvement, although the original gap A basically disappeared, a level difference (i.e., height difference, or step) B between the frame 12 and the backplate 11 and a new gap A′ between the backplate 11 and the display module 14 easily appeared instead. As for such improvement, the new level difference B between the backplate 11 and the frame 12 will cause the frame 12 to protrude with respect to the backplate 11, i.e., the two are not in the same plane, while the existence of the new gap A′ will cause the backplate 11 to be easily deformed or uneven after assembly. Therefore, the appearance of the whole digital art product after such improvement is still unsatisfactory.

To this end, the inventors of the present application have made continuous attempts and improvements. In some exemplary embodiments of the present disclosure, a backplate and a protective cover for an electronic product are provided to solve the problem that there is still a level difference between the backplate 11 and the frame 12 after the backplate and the frame are made to have cooperating sloped surfaces which causes the frame 12 to protrude with respect to the backplate 11 (i.e., the two are not in the same plane) and the appearance is still unsatisfactory, and the improved solution is more suitable for practical use.

In order to solve the above technical problem, the general idea of the technical solution of the backplate and the protective is cover for an electronic product according to some exemplary embodiments of the present disclosure is as follows.

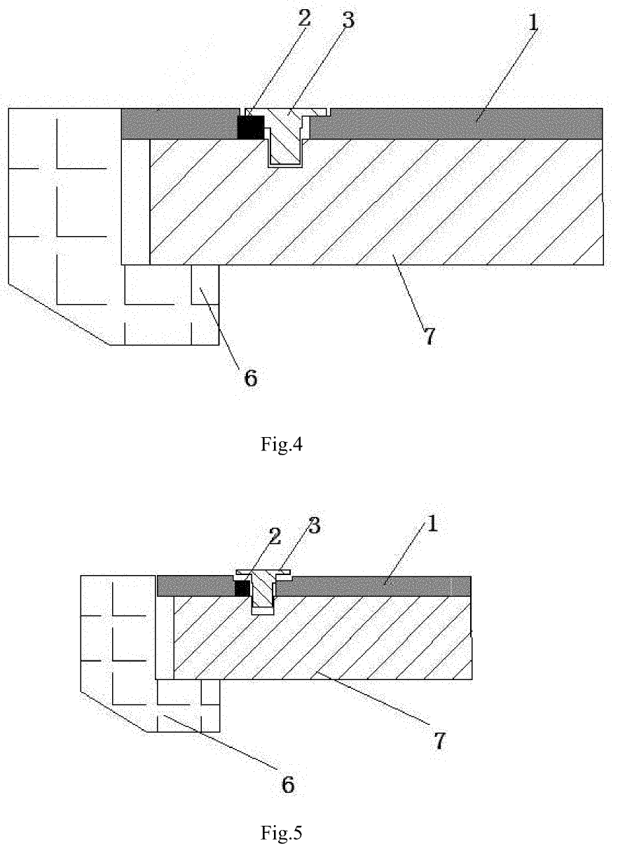

Referring to FIG. 3, some exemplary embodiments of the present disclosure provide a backplate including a backplate body 1, a movable portion 2, and ejection structures 3. The backplate body 1 is made of an elastic material. The movable portion 2 is disposed at the peripheral edge of the backplate body 1. Specifically, the movable portion 2 may be embedded in the edge portion of the backplate body 1 as shown in FIG. 3, or may be disposed around the periphery of the backplate body 1 to serve as the outermost edge portion of the backplate body 1. The ejection structures 3 are arranged on the backplate body 1.

The ejection structure 3 shown in FIG. 3 is in a first operating state (i.e., the ejection structure 3 is in a locked operating state, i.e., an operating state in which the movable portion 2 and/or the edge portion of the backplate body 1 is pushed or squeezed by the ejection structure 3 to make the movable portion 2 and/or the edge of the backplate body 1 abut against the frame 6). When the ejection structure 3 is in this first operating state, the movable portion 2 and the edge portion of the backplate body 1 are ejected in a direction away from the center of the backplate body 1, so that the edge portion of the backplate body 1 extends in a direction away from the center.

Specifically, in order to solve the problem that there is still a level difference between the backplate and the frame after adopting the sloped surface solution so that the frame protrudes with respect to the backplate, resulting in that the backplate and the frame are not in the same plane and there are still defects in appearance, wherein the level difference refers to the height deviation of the surface positions of two elements caused by machining precision or assembly precision, some exemplary embodiments of the present disclosure provide a backplate is including a backplate body 1, a movable portion 2 and an ejection structure 3. The backplate body 1 is made of an elastic material, the movable portion 2 is arranged at the peripheral edge of the backplate body 1, and the ejection structures 3 are arranged in the backplate body 1. The ejection structure 3 may or may not be in contact with the movable portion 2.

As shown in FIG. 3, when in the first operating state, the ejection structure 3 ejects the movable portion 2 and the edge portion of the backplate body 1 together in a direction away from the center of the backplate body 1, so that the edge portion of the backplate body 1 extends in a direction away from the center, thereby filling the gap between the backplate body 1 and the frame 6. The first operating state is the operating state in which the ejection structure 3 is locked, i.e. the movable portion 2 and/or the edge portion of the backplate body 1 is pushed or squeezed to make the edge of the movable portion 2 and/or the backplate body 1 abut against the frame 6.

In the exemplary embodiment described above, the rigid material of the backplate body 1 is replaced with an elastic material, which alleviates the problem that the deformation of the rigid material is not sufficient to fill the gap between the backplate body 1 and the frame 6. In addition, in the present disclosure, the movable portion 2 and the ejecting portion 3 are arranged at the peripheral edge portion of the backplate body 1. By virtue of the elastically deformable property of the backplate body 1, the edge portion of the backplate body 1 and the movable portion 2 are ejected through the ejection structure 3, so that the edge portion of the backplate body 1 extends in a direction away from the center, and the gap between the backplate body 1 and the frame 6 is filled, so as to solve the appearance defect problem existing in the connection between the backplate and the frame 6.

In this article, the term “and/or” is only an association is relationship describing associated objects, which means that there can be three kinds of relations, for example, A and/or B. it can be specifically understood in the following way: A and B can be included simultaneously, A can exist alone, or B can exist alone, and any of the above three relations can exist.

Further, in some exemplary embodiments of the present disclosure, the movable portion 2 is disposed through the peripheral edge portion of the backplate body 1 or the movable portion 2 is disposed around the edge of the backplate body 1.

Specifically, in order to achieve flexible design, in the technical solution adopted in the present disclosure, on the one hand, the movable portion 2 can be disposed through the edge portion of the backplate body 1, that is, the edge portion of the backplate body 1 is in contact with the frame 6. In this case, when in the first operating state, the ejection structure 3 first ejects the movable portion 2 outward away from the center of the backplate body 1, and then causes the edge portion of the backplate body 1 to deform or displace. Since the backplate body 1 is made of a deformable elastic material, the edge portion of the backplate body 1 is ejected in the same direction while or after the movable portion 2 is ejected, and furthermore the gap between the backplate body 1 and the frame 6 is filled by the deformation of the edge portion of the backplate body 1. On the other hand, the movable portion 2 may be directly arranged around the edge of the backplate body 1 to serve as the edge portion of the backplate body 1, that is, the movable portion 2 is in contact with the frame 6. In this case, when the ejection structure 3 is in the first operating state, the edge portion of the backplate body 1 between the movable portion 2 and the ejection structure 3 is ejected in the direction away from the center of the backplate body 1. Since the backplate body 1 is made of a deformable elastic material, the edge portion of the backplate body 1 is deformed and/or displaced, and the movable portion 2 is also caused to move in the direction away from the center of the backplate body 1 as a whole until the movable portion 2 is in close contact with the frame 6 to fill the gap between the backplate body 1 and the frame 6

Further, in some exemplary embodiments of the present disclosure, the ejection structure 3 includes a locking portion 31 and an ejecting portion 32. The locking portion 31 is arranged at a first end of the ejection structure 3 and is used for connecting the backplate body 1 and a front object 7. The ejecting portion 32 is disposed at a second end of the ejection structure 3 and moves synchronously with the locking portion 31 for ejecting the movable portion 2 or the edge portion of the backplate body 1. The front object 7 may be a display module of an electronic device such as an electronic picture screen or an electronic photo frame, or a protective cover or a mounting frame of the display module.

Specifically, in order to realize the deformation of the backplate body 1 and the connection between the backplate body 1 and the front object 7 at the same time, in the technical solution adopted by the present disclosure, the ejection structure 3 includes a locking portion 31 having a locking function and an ejecting portion 32 having an ejecting function. The locking portion 31 and the ejecting portion 32 are arranged adjacent to each other and are arranged at two ends of the ejection structure 3. As the locking portion 31 is locked to the backplate body 1, the ejecting portion 32 moves synchronously with the locking portion 31, thereby embedding its own volume into the backplate body 1 to push and/or squeeze the movable portion 2 or the edge portion of the backplate body 1. Of course, the ejection structure 3 can also be provided with a grip portion, and the grip portion is connected with the ejecting portion 32. On the one hand, the grip portion is convenient to grip the whole ejection structure 3, and on the other hand, the grip portion can be made into a head portion similar to a countersunk screw, so that when the ejection structure 3 is embedded in the backplate body 1, the end surface of the grip portion is flush with the outer surface of the backplate body 1, further beautifying the appearance of the whole electronic product.

Further, in some exemplary embodiments of the present disclosure, the outer periphery of the locking portion 31 is provided with locking threads, that is, the entire ejection structure 3 is in the form of an odd-shaped lock screw. The ejecting portion 32 is coaxially arranged with the locking portion 31 and rotates synchronously with the locking portion 31, and the diameter of the ejecting portion 32 is larger than the diameter of the locking thread.

Specifically, in order to simplify the manufacturing process and steps and facilitate the operation, in the technical solution adopted in the present disclosure, the outer periphery of the locking portion 31 is provided with locking threads, i.e., the entire ejection structure 3 is in the form of an odd-shaped lock screw. The backplate body 1 and the front object 7 are connected with each other and locked by tightening the screw, and at the same time, an ejecting portion 32 arranged adjacent to the locking portion 31 is coaxially arranged with the locking portion 31, rotates synchronously with the locking portion 31, and the diameter of the ejecting portion 32 is larger than the diameter of the locking portion 31. During the rotation of the locking portion 31, the locking portion 31 moves toward the front object 7 with respect to the backplate body 1, and the ejecting portion 32 rotates with the locking portion 31 and moves in the same direction, which is equivalent to embedding the ejecting structure 3 into the backplate body 1.Whether the ejecting portion 32 is in direct contact with the edge portion of the backplate body 1 but not with the movable portion 2 causing the edge portion of the backplate body 1 to extend in a direction away from the center thereof and indirectly causing the movable portion 2 to move outward, or the ejecting portion 32 is in direct contact with the movable portion 2 causing the movable portion 2 to extend in a direction away from the center of the backplate and indirectly causing the edge portion of the backplate body 1 to extend outward, the effect of filling the gap by utilizing the outward extension of the edge portion of the backplate body 1 can be achieved.

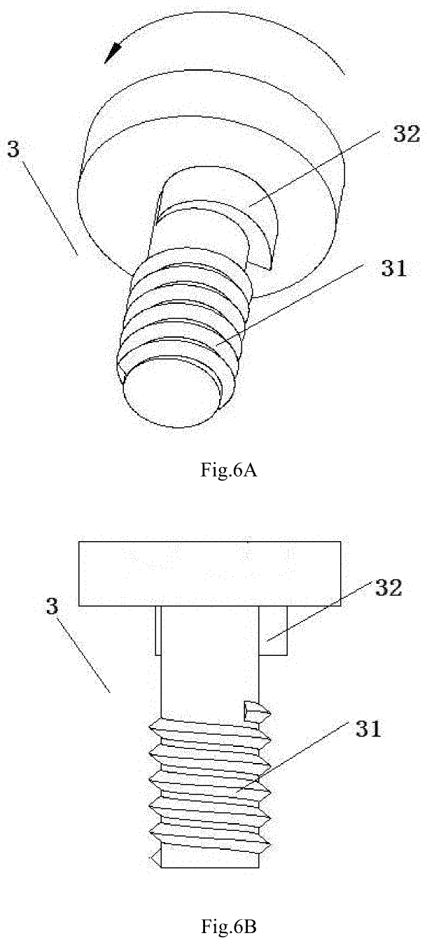

Further, referring to FIGS. 6A and 6B, in some exemplary embodiments of the present disclosure, the locking portion 31 of the ejection structure 3 has a cylindrical shape with a uniform diameter, and the ejecting portion 32 of the ejection structure 3 has a generally cylindrical odd shape. A first portion of the ejecting portion 32 adjacent to the locking portion 31 is cylindrical with a diameter slightly smaller than the diameter of the locking portion 31. A second portion of the ejecting portion 32 at a certain distance from the locking portion 31 in the axial direction is in the shape of a projection, and the outer periphery of the projection is a smooth cylindrical surface. The second portion of the ejecting portion 32 is interposed between the first portion of the ejecting portion 32 and the grip portion. The projection is at least partially disposed at the periphery of the second portion, and the outer diameter of the projection gradually increases along the circumferential direction of the second portion. For convenience of description, the maximum outer diameter of the projection is hereinafter referred to as the first length L1, and the projecting distance of the projection relative to the first portion of the ejecting portion 32 in the radial direction of the ejecting portion 32 is referred to as the second length L2. Optionally, the maximum value of L2 is 10%-40% of L1, for example, the maximum value of L2 is 20%-30% of L1, for example, 25%. Experiments show that this arrangement can not only ensure that the ejection structure 3 has certain strength, but also give consideration to high ejection efficiency. In addition, the size of the first length L1 may be set equal to the maximum gap distance between the backplate body 1 and the frame 6.

Specifically, in order to realize seamless butt joint between the backplate body 1 and the frame 6 simply and conveniently, in the technical solution adopted in the present disclosure, the outer periphery of the locking portion 31 is provided with locking threads, and the projection is at least partially arranged at the periphery of the second portion of the ejecting portion 32, and the outer diameter of the projection gradually increases along the circumferential direction of the second portion, and the maximum outer diameter (i.e., the first length L1) of the projection can be set equal to the maximum gap distance between the backplate body 1 and the frame 6. For example, the ejecting portion 32 is provided with a projection with a gradually increasing diameter in one or less than one circumference of the periphery at a certain height from the locking portion 31. According to the maximum gap distance between the backplate body 1 and the frame 6, the growth amplitude and growth rate of the ejecting portion 32 on the entire circumference of the ejecting portion 32 can be set, and the diameter of the ejecting portion 32 can also be rapidly increased on half of the circumference or even on a quarter of the circumference. For example, referring to FIG. 6A, the diameter of the ejecting portion 32 is rapidly increased on half of the circumference to the maximum gap distance between the backplate body 1 and the frame 6. The maximum outer diameter of the profile of the projection with gradually increasing diameter is equal to the maximum gap distance between the backplate body 1 and the frame 6, that is to say, the ejection structure 3 can be suitable for connection between the backplate and the frame 6 with the same gap size.

Referring to FIG. 4 and FIG. 5, wherein FIG. 5 is a schematic sectional view of the ejection structure 3 in a second operating state (i.e., the ejection structure 3 is in a released unlocked operating state, i.e., an operating state in which no stress is generated on the movable portion 2 and/or the edge portion of the backplate body 1). FIG. 4 is a schematic sectional view of the ejection structure 3 in a first operating state. For example, the ejection structure 3 in the form of a lock screw tightly connects the backplate body 1 and the front object 7 by the locking portion 31 through rotation. As the ejection structure 3 continues to rotate, the ejecting portion 32 continues to move toward the inside of the backplate body 1 together with the locking portion 31. The ejecting portion 32 then touches the movable portion 2, ejects the movable portion 2 until the movable portion 2 cannot be ejected anymore which indicates that the extension amount (radial displacement) of the edge portion of the backplate body 1 due to the ejection effect of the movable portion 2 can just fill the gap between the backplate body 1 and the frame 6 and therefore the edge portion of the backplate body 1 and the frame are in close contact with each other. Or alternatively, the ejecting portion 32 then ejects the edge portion of the backplate body 1 until the edge portion of the backplate body 1 cannot be ejected anymore, which indicates that since the extension or displacement of the edge portion of the backplate body 1 can just fill the gap between the backplate body 1 and the frame 6, the movable portion 2 is in close contact with the frame 6 at this time.

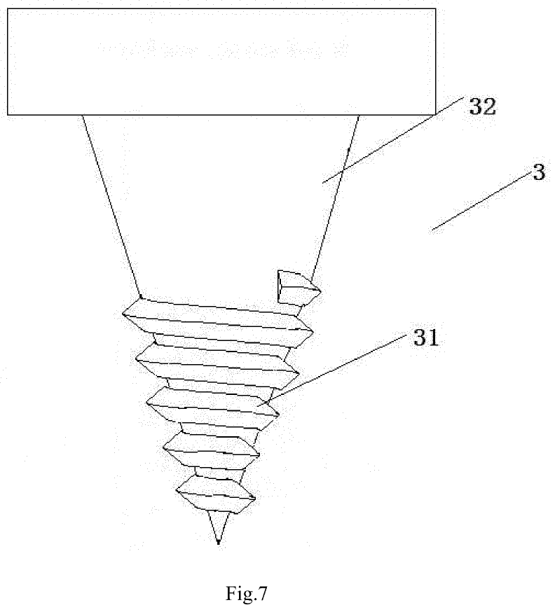

Further, as shown in FIG. 7, in some exemplary embodiments of the present disclosure, the ejection structure is a conical screw. The diameter of the ejecting portion 32 and the diameter of the locking thread (i.e., external thread) of the locking portion 31 gradually decrease in the direction from the head portion to the tail portion of the lock screw. The maximum diameter of the ejecting portion 32 (i.e., the diameter adjacent to the head of the lock screw) is equal to the maximum gap distance between the backplate body 1 and the frame 6.

Specifically, in order to simplify the manufacturing process and realize the ejecting function, in the technical solution adopted by the disclosure, the lock screw is provided as a conical screw, the tip (i.e., the tail end) of the conical screw penetrates through the backplate body 1 to the front object 7 and is rotated and locked, and the diameter of the conical screw gradually increases in the axial direction in the direction away from the conical tip. The maximum diameter of the conical screw is equal to the maximum gap distance between the backplate body 1 and the frame 6. That is to say, the ejecting portion 32 and the locking portion 31 are conical as a whole, except that the outer surface of the ejecting portion 32 is unthreaded. For example, referring to FIG. 7, the diameter of the ejecting portion 32 gradually increases to the maximum diameter in the axial direction in a direction away from the conical tip. The increase rate of the diameter can also be adjusted as needed. If the increase is faster, the height of the ejecting portion 2 in its axial direction is smaller, or alternatively if the increase is slower, the height of the ejecting portion 2 in its axial direction is larger. The maximum diameter of the ejecting portion 32 is equal to the maximum gap distance between the backplate body 1 and the frame 6, that is, the ejection structure 3 of such structure can be applied to the connection between the backplate and the frame 6 with the same gap size. FIG. 7 shows another structural schematic view of the ejection structure 3. The backplate body 1 and the front object 7 are tightly connected through the external threads of the locking portion 31 by rotating the lock screw. As the lock screw continues to rotate, the ejecting portion 32 continues to move towards the inside of the backplate body 1 together with the locking portion 31, and then the ejecting portion 32 touches the movable portion 2, ejects the movable portion 2 until the movable portion 2 cannot be ejected anymore which indicates that the extension amount (radial displacement amount) of the edge portion of the backplate body 1 due to the ejection effect of the movable portion 2 can just fill the gap between the backplate body 1 and the frame 6, and the edge portion of the backplate body 1 is in close contact with the frame 6 at this time. Or alternatively, the ejecting portion 32 ejects the edge portion of the backplate body 1 until the edge portion of the backplate body 1 cannot be ejected anymore, which indicates that the displacement of the movable portion 2 due to the extension of the edge portion of the backplate body 1 can just fill the gap between the backplate body 1 and the frame 6, and the movable portion 2 is in close contact with the frame 6 at this time.

Further, referring to FIG. 9, in some exemplary embodiments of the present disclosure, the backplate further includes ejector rods 5, the ejector rods 5 are disposed between the movable portion 2 and the ejection structures 3, and a first end of the ejector rod 5 is in abutting engagement with the movable portion 2, and a second end of the ejector rod 5 is in contact with the ejection structure 3.

Specifically, in order to make the ejection operation more convenient, in the technical solution adopted in the present disclosure, the ejector rods 5 are arranged between the movable portion 2 and the ejection structures 3, and the ejector rods 5 are in abutting engagement with the ejection structures 3. When the ejection structure 3 performs the ejection operation, the ejector rod 5 is firstly ejected, and then the movable portion 2 is ejected through the ejector rod 5, thus realizing the outward extension deformation of the edge portion of the backplate body 1. Compared with the ejection mode without the ejector rod 5, the addition of the ejector rod 5 causes the ejection operation of the ejection structure to be more labor-saving and convenient.

Further, referring to FIGS. 3, 8 and 9, in some exemplary embodiments of the present disclosure, the movable portion 2 is a strip-shaped movable bar, and adjacent movable bars do not contact each other. Each of the strip-shaped movable bars extends along substantially the entire length direction or width direction of the backplate body 1.

Specifically, in order to let the ejection range to be in conformity with the edge portion of the backplate body 1 and simplify the design procedure, in the technical solution adopted in this disclosure, the movable portion 2 is provided as a strip-shaped movable bar, and at least two ejection structures 3 can be provided for each strip-shaped movable bar at this time, and the two ejection structures 3 are respectively arranged near the two ends of the strip-shaped movable bar. Optionally, the ejection structures 3 may be symmetrically arranged in even numbers with respect to the center of the strip-shaped movable bar, or alternatively one may be arranged at the center position, and a total of odd ejection structures may be arranged with the one at the center as the symmetric center. The strip-shaped movable bar can comprise a rigid material, so that when an outward ejection operation is performed, the movable bar can integrally move outward, which is simple, convenient and labor-saving. In addition, two ends of the adjacent strip-shaped movable bars are not contacted, and the movement of the strip-shaped movable bars is not limited during ejection operation, so that labor is easily saved.

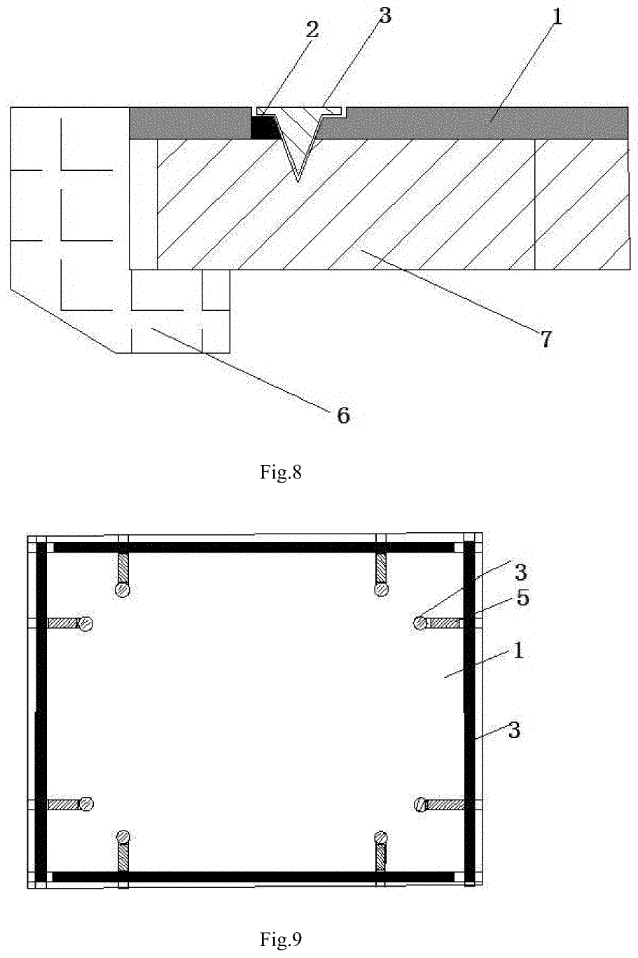

Referring to FIGS. 4 and 8, the shape of the surface of the movable portion 2 contacting with the ejecting portion 32 can be changed correspondingly according to the shape of the ejecting portion 32, such as a vertical surface, a sloped surface or other achievable contact surface.

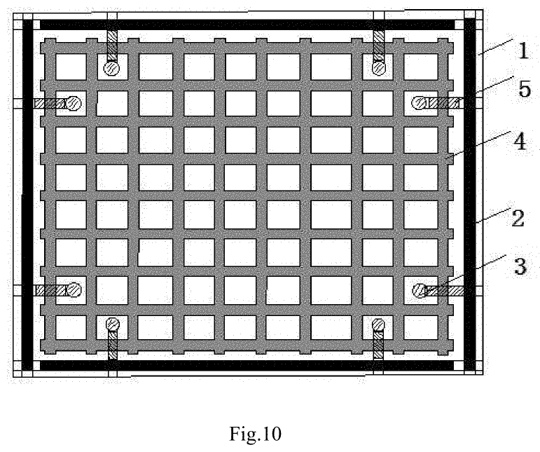

Further, referring to FIG. 10, in some exemplary embodiments of the present disclosure, the backplate further includes a reinforcing portion 4, which is a rigid grid structure. The reinforcing portion 4 is provided on the backplate body 1 at the area other than the movable portion 2, for example, in the area inwards of the strip-shaped movable portion 2.

Specifically, in the specific embodiment adopted in the present disclosure, the reinforcing portion 4 having a rigid grid structure is provided in the backplate body 1, which can enhance the overall strength and surface flatness of the backplate body 1.

It should be noted that in the above exemplary embodiment, the movable portion 2, the ejection structure 3, the reinforcing portion 4, and the ejector rod 5 are all made of rigid materials, such as metal or polycarbonate (PC) plastics, or light aluminum alloy, which can meet the rigidity requirement without increasing the overall weight of the backplate body 1.

Another aspect of the present disclosure also provides a protective cover, which includes the above-mentioned backplate and frame 6. The frame 6 is arranged at the peripheral edge of the backplate to form an accommodating space with the backplate for accommodating the front object 7.

Specifically, the backplate described in the present disclosure can directly adopt the backplate provided in the first aspect, and the specific structure can be seen in the related contents described in the first aspect, which will not be repeated here.

The backplate and the protective cover disclosed by the present disclosure have at least the follow advantages: the material of the backplate body 11 is replaced by an elastic material to solve the problem that the deformation of the rigid material is insufficient to fill the gap between the backplate body 1 and the frame 6. In addition, in the present disclosure, the movable portion 2 and the ejecting portion 32 are cooperatively arranged at the peripheral edge portion of the backplate body 1, and the edge portion of the backplate body 1 and the movable portion 2 are ejected through the ejection structure 3 by virtue of the elastically deformable property of the backplate body 1, so that the edge portion of the backplate body 1 extends in a direction away from the center thereof, and the gap between the backplate body 1 and the frame 6 is filled, so as to solve the problem of appearance defects existing in the connection between the backplate and the frame 6.

It should be understood that although various features and beneficial effects of the present disclosure and specific details of the structure and function of the present disclosure have been set forth in the above description, these contents are merely exemplary, and the specific details thereof, especially the shape, size, number and arrangement of components, may be specifically changed within the scope of the principles of the present disclosure to the overall scope represented by the broad general meaning as claimed in the claims of the present disclosure.

Unless otherwise defined, all technical and scientific terms used in this specification have the same meaning as commonly understood by those skilled in the art to which this disclosure belongs.

Those skilled in the art will understand the term “substantially” herein (such as in “substantially all light” or in “substantially composed of”). The term “substantially” may also include embodiments having “wholly,” “completely,” “all,” etc. Therefore, in the embodiment, the adjective is also substantially removable. Where applicable, the term “substantially” may also refer to 90% or more, such as 95% or more, specifically 99% or more, even more specifically 99.5% or more, including 100%. The is term “comprising” also includes embodiments in which the term “comprising” means “consisting of”. The term “and/or” specifically refers to one or more of the items mentioned before and after “and/or”. For example, the phrase “item 1 and/or item 2” and similar phrases may relate to one or more of items 1 and 2. The term “comprising” may refer to “consisting of” in one embodiment, but may also refer to “including at least a defined category and optionally one or more other categories” in another embodiment.

Furthermore, the terms first, second, third, etc. in this specification and in the claims are used to distinguish between similar elements and do not denote any order, quantity, or importance. It should be understood that the terms so used are interchangeable under appropriate circumstances and that the embodiments of the present disclosure described herein are capable of operation in a different order than described or illustrated herein.

“Up”, “down”, “left” and “right” are only used to indicate the relative positional relationship. When the absolute position of the described object changes, the relative positional relationship may also change accordingly.

It should be noted that the above-mentioned embodiments illustrate rather than limit the present disclosure, and that those skilled in the art will be able to design many alternative embodiments without departing from the scope of the appended claims. In the claims, any reference signs placed between parentheses shall not be construed as limiting the claims. The use of the verb “to include” and its conjugations does not exclude the presence of elements or steps other than those stated in a claim. The words “a” or “an” in the claims of the present disclosure do not exclude plural numbers, and are only intended for convenience of description and should not be construed as limiting the scope of protection of the present disclosure.

The present disclosure may be implemented by means of hardware comprising several distinct elements, and by means of a suitably programmed computer. In the device claim enumerating several devices, several of these devices can be embodied by the same item of hardware. The mere fact that certain measures are recited in mutually different dependent claims does not indicate that a combination of these measures cannot be used to advantage.

The present disclosure is further applicable to devices that include one or more of the characterizing features described in this specification and/or shown in the drawings. The present disclosure further relates to methods or processes that include one or more of the characterizing features described in this specification and/or shown in the drawings.

Various aspects discussed in this disclosure may be combined to provide additional advantages. In addition, those skilled in the art will understand that embodiments can be combined, and more than two embodiments can also be combined. In addition, some features may form the basis of one or more divisional applications.

1. A backplate for an electronic product, comprising:
a backplate body comprising an elastic material and provided with an edge portion and a central portion;
a movable portion arranged at a peripheral edge of the backplate body; and
an ejection structure arranged on the backplate body and having a first operating state,
wherein the ejection structure is configured to eject the edge portion of the backplate body and the movable portion in a direction away from the central portion of the backplate body when the ejection structure is in the first operating state so that the edge portion of the backplate body extends in the direction away from the central portion of the backplate body.

2. The backplate for the electronic product according to claim 1, wherein the movable portion is embedded in the edge portion of the backplate body.

3. The backplate for the electronic product according to claim 1, wherein the movable portion is disposed around an edge of the backplate body.

4. The backplate for the electronic product according to claim 1, wherein the ejection structure comprises a locking portion and an ejecting portion, the locking portion is arranged at a first end of the ejection structure and is configured to connect the backplate body and a front object of the electronic product, and the ejecting portion is arranged at a second end of the ejection structure and configured to move synchronously with the locking portion for ejecting the movable portion or the edge portion of the backplate body outwards.

5. The backplate for the electronic product according to claim 4, wherein the front object is a display module of the electronic product.

6. The backplate for the electronic product according to claim 4, wherein the ejection structure is in a shape of an odd-shaped lock screw as a whole.

7. The backplate for the electronic product according to claim 4, wherein an outer periphery of the locking portion is provided with locking threads, the ejecting portion is coaxially arranged with the locking portion and rotates synchronously with the locking portion, and a maximum diameter of the ejecting portion is larger than a diameter of the locking portion.

8. The backplate for the electronic product according to claim 7, wherein the locking portion of the ejection structure is cylindrical with a uniform diameter, a first portion of the ejecting portion adjacent to the locking portion is cylindrical with a diameter slightly smaller than the diameter of the locking portion, a second portion of the ejecting portion at a certain distance from the locking portion in an axial direction is in a shape of a projection, and an outer periphery of the projection is a smooth cylindrical surface.

9. The backplate for the electronic product according to claim 8, wherein the projection is at least partially disposed at a periphery of the second portion of the ejecting portion, and an outer diameter of the projection gradually increases along a circumferential direction of the second portion.

10. The backplate for the electronic product according to claim 9, wherein a maximum outer diameter of the projection is referred to as a first length L1 and a projecting distance of the projection relative to the first portion of the ejecting portion in a radial direction of the ejecting portion is referred to as a second length L2, a maximum value of L2 is 10%-40% of L1, and a size of the first length L1 is equal to a maximum gap distance between the backplate body and a frame of the electronic product.

11. The backplate for the electronic product according to claim 7, wherein the ejection structure is a conical screw, the diameter of the ejecting portion and the diameter of the locking portion gradually decrease in a direction from a head portion to a tail portion of the conical screw, and the maximum diameter of the ejecting portion is equal to a maximum gap distance between the backplate body and a frame of the electronic product.

12. The backplate for the electronic product according to claim 1, further comprising an ejector rod, wherein the ejector rod is arranged between the movable portion and the ejection structure, and a first end of the ejector rod is in abutting engagement with the movable portion, and a second end of the ejector rod is in contact with the ejection structure.

13. The backplate for the electronic product according to claim 1, wherein the movable portion is a strip-shaped movable bar, and adjacent strip-shaped movable bars are not in contact with each other.

14. The backplate for the electronic product according to claim 1, further comprising a reinforcing portion, wherein the reinforcing portion is arranged in an area of the backplate body other than the movable portion, and the reinforcing portion is in a structure of a rigid grid.

15. The backplate for the electronic product according to claim 1, wherein the movable portion and the ejection structure comprise rigid materials.

16. A protective cover for an electronic product, comprising
a backplate for the electronic product and
a frame,
wherein the backplate for the electronic product comprises:
a backplate body comprising an elastic material and provided with an edge portion and a central portion;
a movable portion arranged at a peripheral edge of the backplate body; and
an ejection structure arranged on the backplate body and having a first operating state
wherein the ejection structure is configured to eject the edge portion of the backplate body and the movable portion in a direction away from the central portion of the backplate body when the ejection structure is in the first operating state so that the edge portion of the backplate body extends in the direction away from the central portion of the backplate body,
wherein the frame is arranged at the peripheral edge portion of the backplate and forming an accommodating space with the backplate for accommodating a front object of the electronic product.

17. The protective cover for the electronic product according to claim 16, wherein the movable portion is embedded in the edge portion of the backplate body.

18. The protective cover for the electronic product according to claim 16, wherein the movable portion is disposed around an edge of the backplate body.

19. The protective cover for the electronic product according to claim 16, wherein the ejection structure comprises a locking portion and an ejecting portion, the locking portion is arranged at a first end of the ejection structure and is configured to connect the backplate body and a front object of the electronic product, and the ejecting portion is arranged at a second end of the ejection structure and configured to move synchronously with the locking portion for ejecting the movable portion or the edge portion of the backplate body outwards.

20. The protective cover for the electronic product according to claim 19, wherein the front object is a display module of the electronic product.
